(19) United States
(12) Patent Application Publication
(10) Pub. No.: US 2024/0209567 A1
(43) Pub. Date: Jun. 27, 2024

(54) PRODUCING COATED TEXTILES USING PHOTO-INITIATED CHEMICAL VAPOR DEPOSITION

(71) Applicant: Soliyarn, Inc., Boston, MA (US)

(72) Inventors: Trisha Lionel Andrew, Hadley, MA (US); Adrian J. Beach, Arlington, MA (US); Sayantani Nandy, Boston, MA (US)

(21) Appl. No.: 18/288,727

(22) PCT Filed: Apr. 29, 2022
(86) PCT No.: PCT/US2022/027041

§ 371 Date: Oct. 27, 2023

Related U.S. Application Data
(60) Provisional application No. 63/181,466, filed on Apr. 29, 2021.

(51) Int. Cl. D06N 3/00; C23C 16/48; C23C 16/52; D06N 3/04; D06N 3/12

(52) U.S. Cl. CPC D06N 3/0086; C23C 16/482; C23C 16/52; D06N 3/042; D06N 3/045; D06N 3/12; D06N 2205/00

(57) ABSTRACT

Systems for producing coated textiles using photo-initiated chemical vapor deposition is presented. The system includes a process chamber and a light source of ultraviolet light. The process chamber includes a transparent window, a substrate stage disposed below the transparent window and a plurality of ports. The ports include a first inlet port and a second inlet port. The first inlet port transports a vapor-phase monomer into the process chamber and the second inlet port transports a vapor-phase initiator into the process chamber. The process chamber is controlled to deposit the monomer and the initiator onto a textile substrate. The light source of ultraviolet light is positioned to introduce the ultraviolet light into the process chamber via the transparent window. The ultraviolet light polymerizes the monomer and the initiator to coat the substrate with a polymer.

### CROSS REFERENCE TO RELATED APPLICATIONS

This application is a national stage application pursuant to 35 U.S.C. § 371 of International Application No. PCT/US2022/027041, filed on Apr. 29, 2022, which claims priority to, and the benefit of, U.S. Provisional Patent Application Ser. No. 63/181,466, filed Apr. 29, 2021, and entitled “PRODUCING COATED TEXTILES USING PHOTO-INITIATED CHEMICAL VAPOR DEPOSITION”; the entirety of which is incorporated herein by reference.

### TECHNICAL FIELD

This application is generally directed to the field of coated textiles, including yarns, fibers and fabrics, and more particularly to producing coated textiles using photo-initiated chemical vapor deposition.

### BACKGROUND

Conventional processes for producing textiles such as fibers, yarns, and fabrics are solvent based. In those processes, raw materials or partially finished fibers and yarns can be colored with dyes, and treated for color fastness, feel, etc. In conventional processes, the items to be processed are introduced into vats containing the treatment chemicals, surfactants, emulsifiers, and lubricants in a solvent. After processing, excess chemicals are disposed of, leading to contaminated rivers and groundwater. The environmental impacts of such processes are significant, but these conventional techniques are widely used because they offer high-throughput production of conventional fibers and fabrics.

In addition to the environmental impact of conventional processes, these processes are also unsuitable for producing hypoallergenic textiles, because inevitably some of the surfactants, emulsifiers or lubricants remain in the finished product.

Therefore, a need in the field exists for improved processes for producing textiles such as yarns, fibers and fabrics, including those that are solvent-free and yield allergen-free products.

### BRIEF DESCRIPTION

Therefore, in one embodiment, a system for producing coated textiles using photo-initiated chemical vapor deposition is presented. The system includes a process chamber and a light source of ultraviolet (UV) light. The process chamber includes a transparent window, a substrate stage disposed below the transparent window and a plurality of ports. The ports include a first inlet port and a second inlet port. The first inlet port transports a vapor-phase monomer into the process chamber and the second inlet port transports a vapor-phase initiator into the process chamber. The process chamber is controlled to deposit the monomer and the initiator onto a textile substrate. The light source of ultraviolet light is positioned to introduce the ultraviolet light into the process chamber via the transparent window. The ultraviolet light photoexcites the initiator, which transfers its excited state energy to and polymerizes the monomer to coat the substrate with a polymer.

In another embodiment, a system for producing coated textiles using photo-initiated chemical vapor deposition is presented. The system includes a process chamber, a light source of ultraviolet light, and a controller. The process chamber includes a transparent window, a substrate stage disposed below the transparent window, a stage chiller disposed below the substrate stage, and a plurality of ports. The ports include a first inlet port, a second inlet port and a vacuum port, wherein the first inlet port transports a vapor-phase monomer into the process chamber and the second inlet port transports a vapor-phase initiator into the process chamber. Additional inlet ports for up to five other vapor-phase co-monomers can also be present. The light source is positioned to introduce the ultraviolet light into the process chamber via the transparent window. The ultraviolet light photoexcites the initiator, which transfers its excited state energy to the monomer and polymerizes it to coat the substrate with a polymer. The controller is configured to deposit the monomer and the initiator onto the substrate concurrent with the polymerization thereof by the ultraviolet light from the light source.

The above embodiments are exemplary only. Other embodiments as described herein are within the scope of the disclosed subject matter.

### BRIEF DESCRIPTION OF THE DRAWINGS

So that the manner in which the features of the disclosure can be understood, a detailed description may be had by reference to certain embodiments, some of which are illustrated in the accompanying drawings. It is to be noted, however, that the drawings illustrate only certain embodiments and are therefore not to be considered limiting of its scope, for the scope of the disclosed subject matter encompasses other embodiments as well. The drawings are not necessarily to scale, emphasis generally being placed upon illustrating the features of certain embodiments. In the drawings, like numerals are used to indicate like parts throughout the various views, in which:

FIG. 1A depicts an embodiment of a coating chamber, in accordance with one or more aspects set forth herein;

FIGS. 1B-1E depict an embodiment of a vapor delivery system, in accordance with one or more aspects set forth herein;

FIGS. 1F & 1G depict an embodiment of a vapor delivery system, in accordance with one or more aspects set forth herein;

FIGS. 2A & 2B depict prior art coatings of textiles;

FIGS. 3A & 3B depict conformal coatings of textiles, in accordance with one or more aspects set forth herein; and

FIGS. 4A-4D depict photo-initiated chemical vapor deposition reactions, in accordance with one or more aspects set forth herein.

Corresponding reference characters indicate corresponding parts throughout several views. The examples set out herein illustrate several embodiments, but should not be construed as limiting in scope in any manner.

### DETAILED DESCRIPTION

The present disclosure relates to a single step, high throughput (1-100 ft/min), photo-initiated chemical vapor deposition (PI-CVD) process that produces polymer films onto flat and patterned substrates including textiles and plastics. This bi-component process proceeds immediately after the introduction of chemical vapors under low vacuum pressures (0.001-10 Torr) initiated by UV-C light to form poly(acrylate), poly(styrene), and poly(vinyl ether) polymers. These coatings have enhanced mechanical robustness through an increase of interfacial grafting, abrasion resistance, and wash stability. Zero wastewater and very little hazardous waste products are generated during production. The present technique may be used to coat a textile with a waterproof coating, an anti-viral coating, an electrically conductive coating, or any other coating required.

Advantageously, the present technique does not require emulsifiers or surfactants, or any solvent, and is free of wastewater generation. Specifically, these techniques, including conjugated polymer production, eliminate worries about solvation shells, immiscibility, solvent-substrate interactions, or solubility of the growing polymer chains. Real-time control over film thickness and nanostructure of growing films may be readily achieved by controlling the flow rates of the monomer and initiator.

Advantages of the present disclosure also include simplicity. The present process uses no surfactants and emulsifiers as compared to conventional processes. Further, no carrier gas is necessary. In one example, the introduction of light is simpler to operate, fix, and design than a filament heater (requiring filament wiring, harness, and power supply).

Numerous reactor geometries may be employed in the present technique. For example, the shape of the reactor may be square, circular, etc. The overall dimension could be any size needed, including for example purposes between 10×10×10 inches and 250×250×250 inches.)

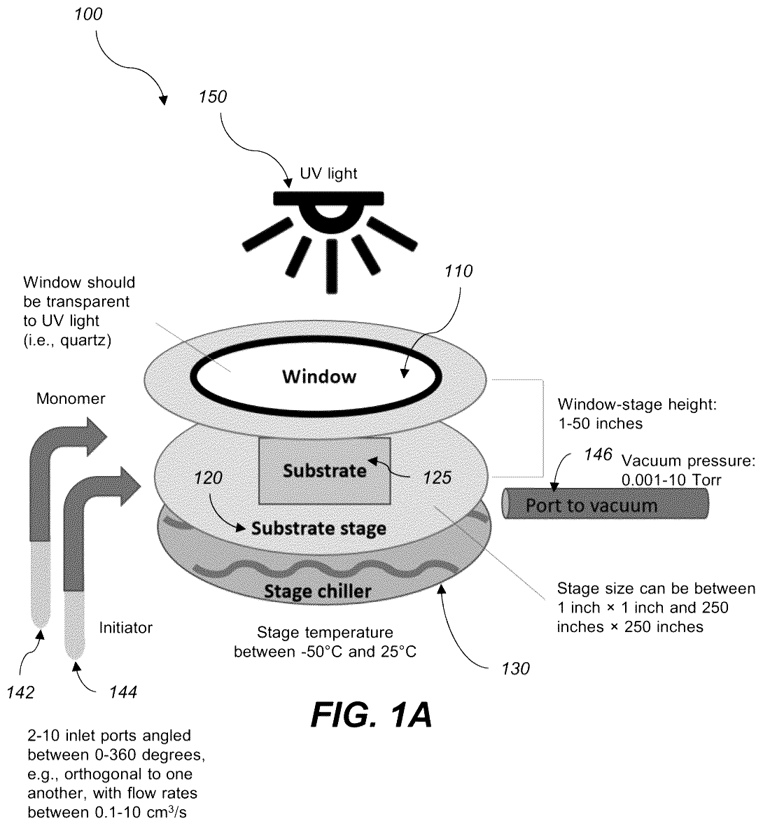

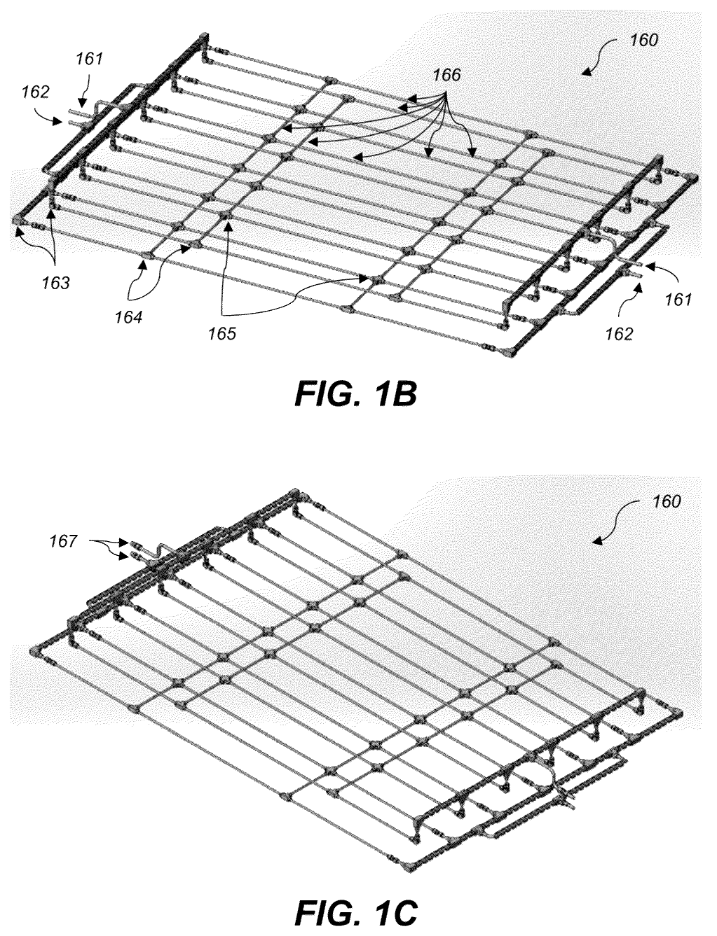

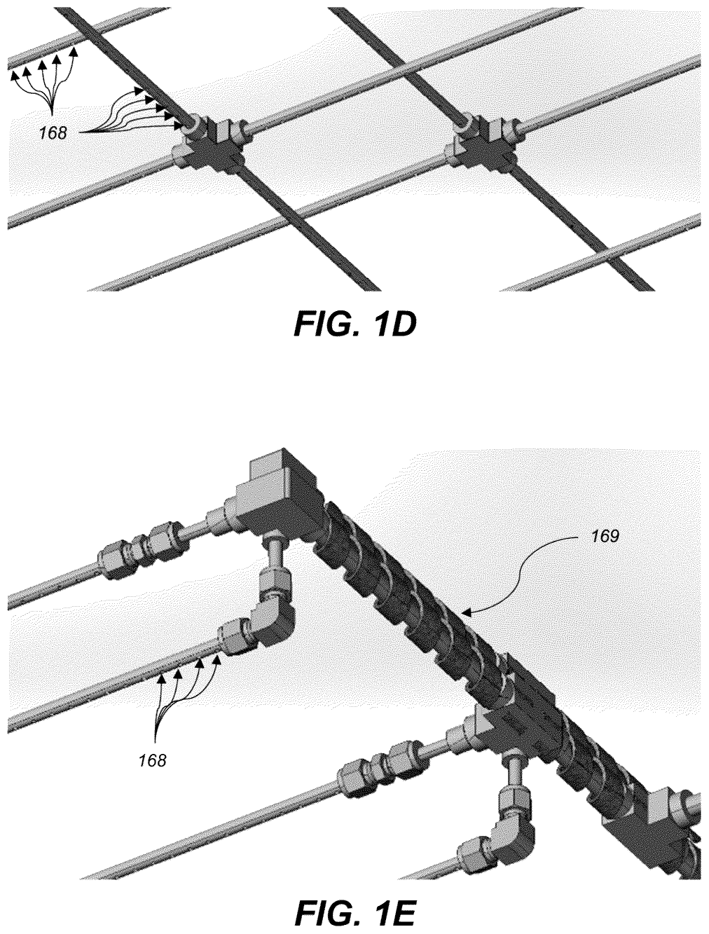

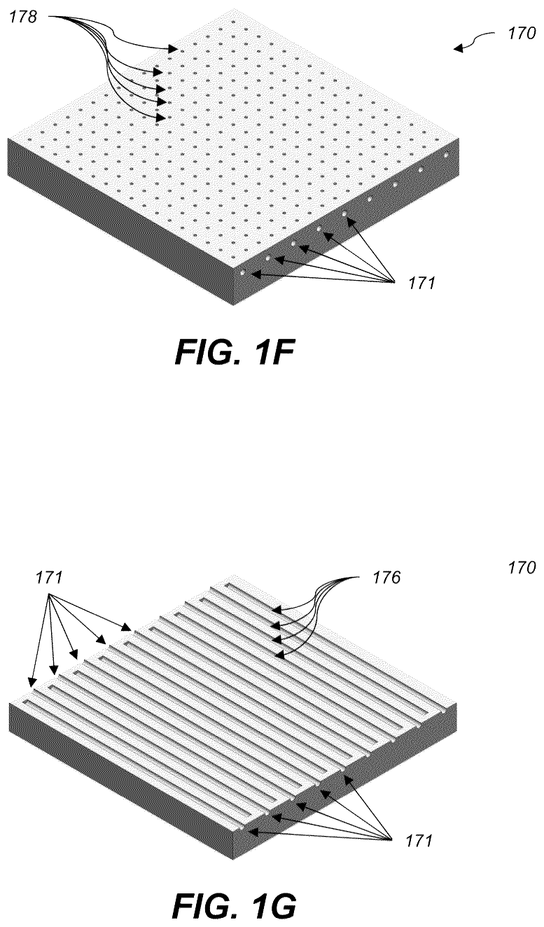

FIG. 1A depicts an embodiment of a system that includes a coating process chamber 100 and a light source 150. Process chamber 100 includes a transparent window 110, a substrate stage 120 disposed below the transparent window 110, a stage chiller 130 disposed below the substrate stage 120, and a plurality of ports 142-146. The ports 142-146 include a first inlet port 142, a second inlet port 144 and a vacuum port 146. The first inlet port transports 142 a vapor-phase monomer into the process chamber. The second inlet port 144 transports a vapor-phase initiator into the process chamber. Five more inlet ports to transport up to five vapor-phase co-monomers into the process chamber can also be present.

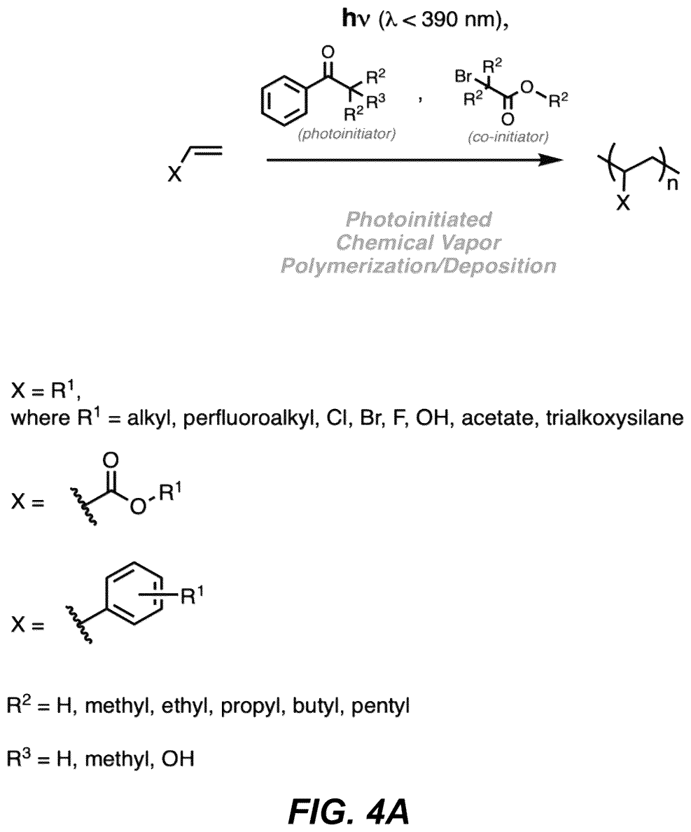

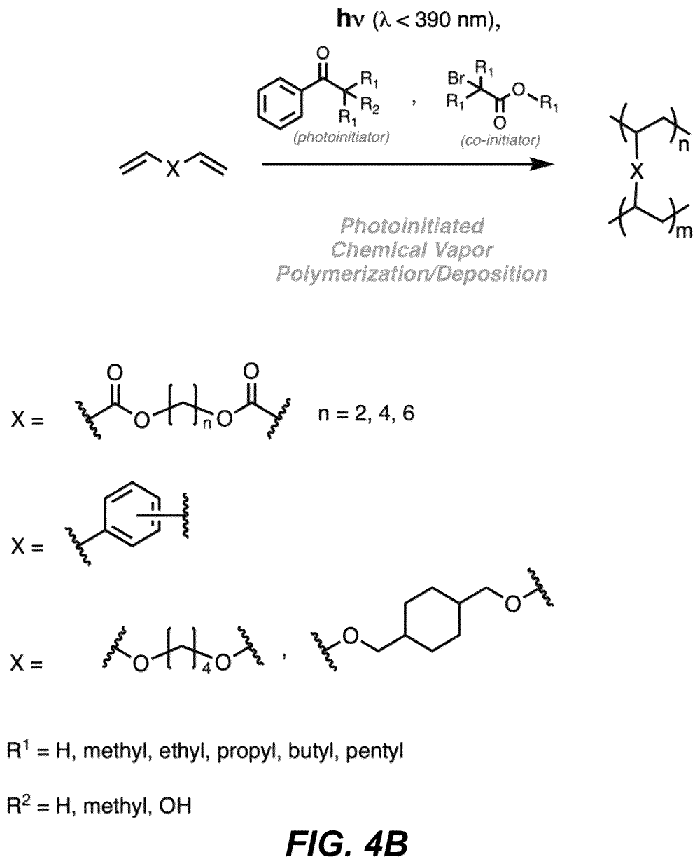

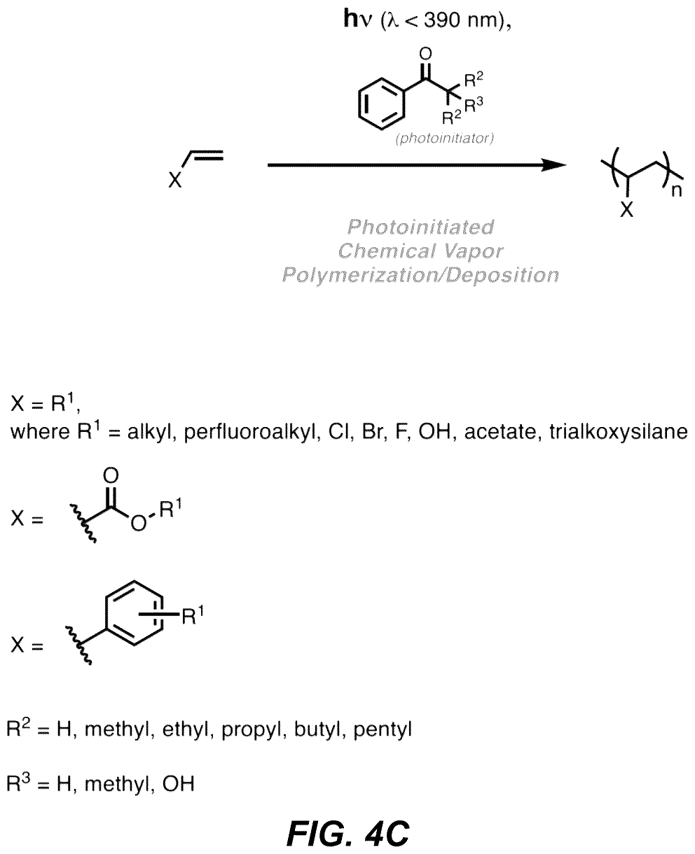

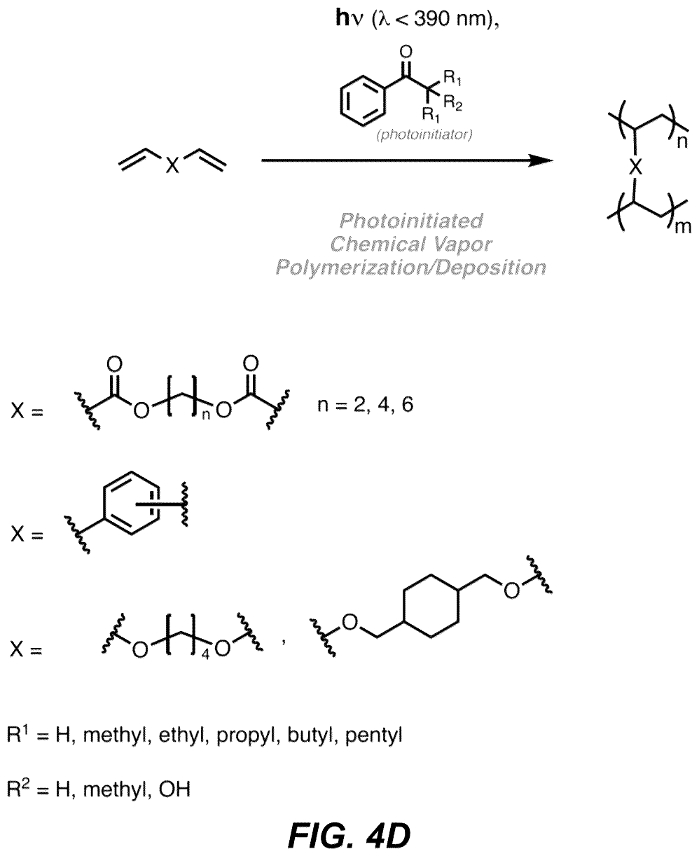

The light source 150 is a source of ultraviolet light (wavelength<390 nm). As depicted in FIG. 1A, light source 150 is positioned to introduce the ultraviolet light into the process chamber 100 via the transparent window 110. After introduction of the UV light, the UV light polymerizes the monomer and the initiator to coat the substrate 125 with a polymer. The reactions are depicted in FIGS. 4A-4D. Due to the reaction rates, throughput rates of 1-100 ft/min have been achieved.

In addition, a controller (not shown) may be used to control deposition of the monomer and the initiator onto the substrate 125 so that it is concurrent with the polymerization thereof by the ultraviolet light from the light source 150.

In one embodiment, the stage chiller 130 is configured to maintain the substrate at a selected temperature between −50 and 25 degrees Celsius. In another embodiment, the vacuum port 146 is configured to maintain a vacuum of between 0.001 to 10 Torr. In a further embodiment, the first inlet port 142 and the second inlet port 144 are each configured with a flow rate of between 0.1 to 10 cubic centimeters per second. In one embodiment first inlet port 142 is orthogonal to second inlet port 144. Optionally, additional inlet ports, e.g., 2-8 additional inlet ports, may be positioned at angles between 0 and 360 degrees from each other.

In one embodiment, reagents, including monomers and initiators are delivered via vapor delivery system 160. Vapor delivery system 160 comprises a plurality of pipes 166 as depicted in FIGS. 1B-1D. In one embodiment, monomers, initiators and/or other reagents enter vapor delivery system 160 via inlets 161 and 162. In another embodiment, pipes 166 are coupled using connectors such as L-connectors 163, T-connectors 164, and X-connectors 165. Optionally, inlet 161 and/or 162 may be sealed, e.g., using caps 167 as shown in FIG. 1C.

FIG. 1D is a close-up of vapor delivery system 160 showing holes 168 in pipes 166 through which vapor exits into process chamber 100. Holes 168 are also shown in the close-up view of vapor delivery system 160 in FIG. 1E. In further embodiments, vapor delivery system 160 comprises a heating element 169, e.g., resistive heating tape wrapped around one of more pipes 166.

In a further embodiment, vapor delivery system 170 comprises a substrate platform comprising inlet holes 171 and outlet holes 178 as illustrated in FIG. 1F. FIG. 1G is a cross-sectional view of vapor delivery system 170 that shows the path from inlet holes 171 through channels 176 to arrive at outlet holes 178 (FIG. 1F).

Advantageously, the system does not include or require a decomposition of peroxides in order to coat the textile substrate due to the novel photo-initiated polymerization process. In one embodiment, the polymer coating the textile substrate 125 comprises one of a poly(acrylate), a poly(styrene), or a poly(vinyl ether) polymer. In another embodiment, the ultraviolet light from the light source 150 comprises a wavelength of less than or equal to 390 nanometers. In another embodiment, the polymer coating the textile substrate 125 comprises p-doped poly(3,4-ethylenedioxythiophene).

The following applications of this technique are within the scope of this disclosure.

Water-resistant coatings—Coatings that protect textiles from wetting and water absorption.

PFC-free water-resistant coatings: Waterproof coatings that do not contain perfluorinated compounds.

Soil-resistant coatings: Coatings that protect the textile from soiling due to dirt, blood, oils, and other hard to protect substances.

SFM (Spatial fluid management); Coating that use a combination of hydrophobic and hydrophilic channels to redirect fluid throughout a textile.

Antimicrobial coating: Coatings that actively kill microbes on the surface of the substrate.

Anti-corrosion films: Coatings that protect the substrate from oxidizing or corroding upon exposure to salt.

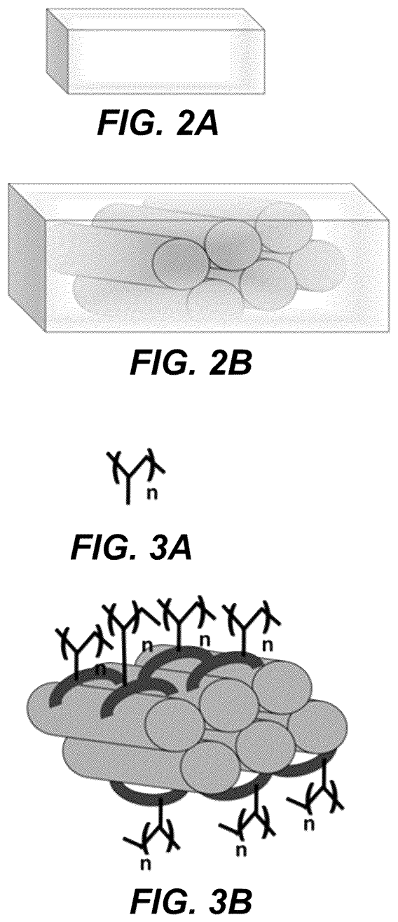

Turning next to FIGS. 2A & 2B, the limitations of the prior art are clear, in that a conventional coating creates an inflexible shell around the substrate (FIG. 2A), which is not conducive to flexibility required for a wearable garment. FIG. 2B illustrates substrate fibers embedded within the inflexible shell depicted in FIG. 2A.

By contrast, as shown in FIGS. 3A & 3B, the textile substrate 125 comprises a fabric, and the coating is deposited conformally around at least some fibers of the fabric. Some properties of the novel coatings will now be explained. Note the differences between FIGS. 3A & 3B and 2A & 2B. In one embodiment, the coating comprises a polymer, such as the one depicted in the schematic representation shown in FIG. 3A. FIG. 3B shows chemical grafting of the polymer of FIG. 3A to the fiber surface. The coating illustrated in FIG. 3B exhibits superior properties over a coated layer that sits on the surface in bulky form as shown in FIGS. 2A and 2B.

Turning next to FIGS. 4A & 4B, the general structure of photo initiators and co-initiators are shown as well as the general process of polymerization directly below. Three structures for poly(vinyl ether), poly(acrylate) and poly(styrene) are shown followed by allowed groups for R2 and R3.

In another embodiment, no co-initiator is included in the polymerization process as shown in FIGS. 4C & 4D. The general structure of photo initiators are shown as well as the general process of polymerization directly below. Three structures for poly(vinyl ether), poly(acrylate) and poly(styrene) are shown followed by allowed groups for R2 and R3.

During the deposition process, the coating has great efficacy, including high amounts of interfacial grafting-covalent bonding between growing film and substrate. Further, there is high abrasion resistance and increased wash stability, due at least in part to the conformality of the coating.

First, a completely fluorine-free coating for waterproof or oil proof applications may be obtained since no solvent is needed to form the coating. Applicant has observed that the coatings formed using the present technique have high contact angles. The contact angle is the metric used to quantify the phobicity of a coating. For example, a test is conducted where a droplet of either an oil or water is put on the surface and angle of the droplet relative to surface normal is calculated by looking at the droplet from the side. The higher the value of this contact angle, the more phobic the surface is to the droplet. High contact angles for a droplet of oil indicate an oil proof surface and high contact angles for a droplet of water indicate a waterproof material. Conventional techniques require the use of fluorinated or perfluorinated materials for oil/waterproof surfaces (Spray, electrodepo, melt, etc.). By contrast, the present PFC-free formulation is a grafted hydrocarbon polymer coating that causes water repellency (water contact angles between 130° and 180°), oil repellency (oil contact angles between 80° and 150°) and decreases water absorption (200× less compared to non-coated) while maintaining the original porosity of the textile on highly textured surfaces. The coating is completely free of PFCs while being composed of a bi-component monomer and initiator formulation made of commercially available chemicals. This formulation has a low environmental impact that produces zero wastewater and is solvent free.

Next, a specific working example of one embodiment shall be discussed.

Step 1: Load the sample stage with the fabric, ensuring that the fabric makes close, uniform physical contact with the stage.

Step 2: Close all valves, turn on the pump, and fully open the pump valve.

Step 3: Add 3 mL of monomer stabilized with 5 wt % of a thermal polymerization inhibitor to a Swagelok stainless steel ampule.

Step 4: Add 2.7 mL of a photoinitiator and 0.3 mL of an alpha-haloester to a Swagelok stainless steel ampule.

Step 5: Screw Swagelok ampules with adjustable wrench onto the chamber ports until ampule does not swivel.

Step 6: When a base pressure of <100 mTorr is achieved, turn on stage chiller and allow it to reach <0° C.

Step 7: Vent initiator ampule only by turning needle valve dial ⅛th turn. Venting is done when pressure increases by about 20-30 mTorr per tube, then decreases back to base pressure.

Step 8: Detect Leaks, if any: If pressure continues to increase, there is a leak somewhere in the tubing. Leaks can be checked by watching pressure while vacuum valve is closed and needle valves are open.

Step 9: After venting out, wrap tubing with heat wrap. Double check thermocouples and inlet wrapping.

Step 10: Close needle valve, plug in heat tapes, and heat to the correct temperatures: Monomer: 120° C.; Initiator: 120° C.

Step 11: Begin heating initiator. Once heated, begin heating monomer. Once monomer and initiator reach their temperatures, set timer for 10 minutes, allowing thermal equilibrium. Stage temperature should be <0° C.

Step 12: Close vacuum valve.

Step 13: Deposition: Place UV lamp box on top of chamber, and turn on the UV lamps.

Step 14: Slowly crack open both initiator valve first, to ⅛ turn and the open monomer valve by ⅛ turn after 30 seconds. QCM Rate should jump up to at least 5 Angstroms per second after each valve is opened.

Step 15: Set timer for 30 minutes, after which the deposition will be complete.

Step 16: Post Deposition: When deposition time is reached, set pump opening to 0%, unplug heat wraps, remove thermocouples.

Step 17: Close monomer and initiator valves.

Step 18: Turn off UV lamps.

Step 19: Power off Heat Wraps, untie them from Swagelok SS Vials.

Step 20: Allow Monomer and Initiator to cool down to 30° C. before measuring remaining monomer and initiator.

Step 21: Record final pressure and film thickness. Open blank valves to bring chamber back to atmosphere.

Further details may be found in, U.S. Patent Publication No. 2019/0230745 A1 (Andrew, Zhang and Baima), published Jul. 25, 2019, and entitled “Electrically-heated fiber, fabric, or textile for heated apparel,” and U.S. Patent Publication No. 2018/0269006 A1 (Andrew and Zhang), published Sep. 20, 2018, and entitled “Polymeric capacitors for energy storage devices, method of manufacture thereof and articles comprising the same,” each of which is incorporated herein in its entirety.

1. A system for producing coated textiles using photo-initiated chemical vapor deposition, the system comprising:
a process chamber comprising:
a transparent window;
a substrate stage disposed below the transparent window; and
a plurality of ports comprising a first inlet port and a second inlet port,
wherein the first inlet port transports a vapor-phase monomer into the process chamber and the second inlet port transports a vapor-phase initiator into the process chamber, wherein the process chamber is controlled to deposit the monomer and the initiator onto a textile substrate; and
a light source of ultraviolet light, light source being positioned to introduce the ultraviolet light into the process chamber via the transparent window, wherein the ultraviolet light polymerizes the monomer and the initiator to coat the substrate with a polymer.

2. The system of claim 1, wherein the process chamber further comprises a stage chiller disposed below the substrate stage, the stage chiller configured to maintain the substrate at a selected temperature between −50 and 25 degrees Celsius.

3. The system of claim 1, wherein the plurality of ports further comprises a vacuum port, and the vacuum port is configured to maintain a vacuum of between 0.001 to 10 Torr.

4. The system of claim 1, wherein the first and second inlet ports are each configured with a flow rate of between 0.1 to 10 cubic centimeters per second.

5. The system of claim 1, wherein the system does not include a decomposition of peroxides in order to coat the textile substrate.

6. The system of claim 1, wherein the process chamber is controlled to deposit the monomer and the initiator onto the substrate concurrent with the polymerization thereof by the ultraviolet light from the light source.

7. The system of claim 1, wherein the textile substrate comprises a fabric, and the coating is deposited conformally around at least some fibers of the fabric.

8. The system of claim 1, wherein the polymer coating the textile substrate comprises one of an acrylate, a polystyrene, or a poly(vinyl) polymer.

9. The system of claim 1, wherein the ultraviolet light from the light sources comprises a wavelength of less than or equal to 390 nanometers.

10. The system of claim 1, wherein the polymer coating the textile substrate comprises p-doped poly(3,4-ethylenedioxythiophene).

11. A system for producing coated textiles using photo-initiated chemical vapor deposition, the system comprising:
a process chamber comprising:
a transparent window;
a substrate stage disposed below the transparent window;
a stage chiller disposed below the substrate stage; and
a plurality of ports comprising a first inlet port, a second inlet port and a vacuum port, wherein the first inlet port transports a vapor-phase monomer into the process chamber and the second inlet port transports a vapor-phase initiator into the process chamber;
a light source of ultraviolet light, light source being positioned to introduce the ultraviolet light into the process chamber via the transparent window, wherein the ultraviolet light polymerizes the monomer and the initiator to coat the substrate with a polymer; and
a controller, the controller configured to deposit the monomer and the initiator onto the substrate concurrent with the polymerization thereof by the ultraviolet light from the light source.

12. The system of claim 11, wherein the stage chiller is configured to maintain the substrate at a selected temperature between −50 and 25 degrees Celsius.

13. The system of claim 11, wherein the vacuum port is configured to maintain a vacuum of between 0.001 to 10 Torr.

14. The system of claim 11, wherein the first and second inlet ports are each configured with a flow rate of between 0.1 to 10 cubic centimeters per second.

15. The system of claim 11, wherein the system does not include a decomposition of peroxides in order to coat the textile substrate.

16. The system of claim 11, wherein the textile substrate comprises a fabric, and the coating is deposited conformally around at least some fibers of the fabric.

17. The system of claim 11, wherein the polymer coating the textile substrate comprises one of an acrylate, a polystyrene, or a poly(vinyl) polymer.

18. The system of claim 11, wherein the ultraviolet light from the light sources comprises a wavelength of less than or equal to 390 nanometers.

19. The system of claim 11, wherein the polymer coating the textile substrate comprises p-doped poly(3,4-ethylenedioxythiophene).
